(19) United States
(12) Patent Application Publication
(10) Pub. No.: US 2010/0038632 A1
(43) Pub. Date: Feb. 18, 2010

(54) ELECTROLUMINESCENT DEVICE

(76) Inventors: Subramaniam Ganeshamurugan, London (GB); Pooopathy Kathirgamanathan, North Harrow (GB); Muttulingam Kumaraverl, London (GB); Seenivasagam Ravichandran, London (GB); Sivagnanasundram Surendrakumar, Middlesex (GB)

Correspondence Address: David Silverstein;Andover IP Law, 44 Park Street Suite 300, Andover, MA, 01810, US

(21) Appl. No.: 12/309,424

(22) PCT Filed: Jul. 26, 2007
(86) PCT No.: PCT/GB2007/050451

§ 371 Date: Jan. 20, 2009

(30) Foreign Application Priority Data
Jul. 26, 2006 (GB) 0614847.2

(51) Int. Cl. H01L 51/54; H01L 51/52

(52) U.S. Cl. 257/40; 257/98; 313/504; 257/E51.026

(57) ABSTRACT

An OLED with a donor which is doped metal quinolate in which the metal is a transition metal in the four or five valent state.

### FIELD OF THE INVENTION

The present invention relates to an electroluminescent device which can emit light of different colours.

### BACKGROUND TO THE INVENTION

Materials which emit light when an electric current is passed through them are well known and used in a wide range of display applications. Liquid crystal devices and devices which are based on inorganic semiconductor systems are widely used, however these suffer from the disadvantages of high energy consumption, high cost of manufacture, low quantum efficiency and the inability to make flat panel displays.

Patent application WO98/58037 describes a range of lanthanide complexes which can be used in electroluminescent devices which have improved properties and give better results. Patent Applications PCT/GB98/01773, PCT/GB99/03619, PCT/GB99/04030, PCT/GB99/04028, PCT/GB00/00268 describe electroluminescent complexes, structures and devices using rare earth chelates.

Typical electroluminescent devices which are commonly referred to as optical light emitting diodes (OLEDS) comprise an anode, normally of an electrically light transmitting material, a layer of a hole transmitting material, a layer of the electroluminescent material, a layer of an electron transmitting material and a metal cathode.

U.S. Pat. No. 5,128,587 discloses an electroluminescent device which consists of an organometallic complex of rare earth elements of the lanthanide series sandwiched between a transparent electrode of high work function and a second electrode of low work function with a hole conducting layer interposed between the electroluminescent layer and the transparent high work function electrode and an electron conducting layer interposed between the electroluminescent layer and the electron injecting low work function anode. The hole conducting layer and the electron conducting layer are required to improve the working and efficiency of the device. The hole conducting or transportation layer serves to transport holes and to block the electrons, thus preventing electrons from moving into the electrode without recombining with holes. The electron conducting or transporting layer serves to transport electrons and to block the holes, thus preventing holes from moving into the electrode without recombining with holes. The recombination of carriers therefore mainly or entirely takes place in the emitter layer.

As described in U.S. Pat. No. 6,333,521 this mechanism is based upon the radiative recombination of a trapped charge. Specifically, OLEDs are comprised of at least two thin organic layers between an anode and a cathode. The material of one of these layers is specifically chosen based on the material's ability to transport holes, a “hole transporting layer” (HTL), and the material of the other layer is specifically selected according to its ability to transport electrons, an “electron transporting layer” (ETL). With such a construction, the device can be viewed as a diode with a forward bias when the potential applied to the anode is higher than the potential applied to the cathode. Under these bias conditions, the anode injects holes (positive charge carriers) into the HTL, while the cathode injects electrons into the ETL. The portion of the luminescent medium adjacent to the anode thus forms a hole injecting and transporting zone while the portion of the luminescent medium adjacent to the cathode forms an electron injecting and transporting zone. The injected holes and electrons each migrate toward the oppositely charged electrode. When an electron and hole localise on the same molecule, a Frenkel exciton is formed. These excitons are trapped in the material which has the lowest energy. Recombination of the short-lived excitons may be visualized as an electron dropping from its conduction potential to a valence band, with relaxation occurring, under certain conditions, preferentially via a photoemissive mechanism.

The materials that function as the ETL or HTL of an OLED may also serve as the medium in which exciton formation and electroluminescent emission occur. Such OLEDs are referred to as having a “single heterostructure” (SH). Alternatively, the electroluminescent material may be present in a separate emissive layer between the HTL and the ETL in what is referred to as a “double heterostructure” (DH).

In a single heterostructure OLED, either holes are injected from the HTL into the ETL where they combine with electrons to form excitons, or electrons are injected from the ETL into the HTL where they combine with holes to form excitons. Because excitons are trapped in the material having the lowest energy gap, and commonly used ETL materials generally have smaller energy gaps than commonly used HTL materials, the emissive layer of a single heterostructure device is typically the ETL. In such an OLED, the materials used for the ETL and HTL should be chosen such that holes can be injected efficiently from the HTL into the ETL. Also, the best OLEDs are believed to have good energy level alignment between the highest occupied molecular orbital (HOMO) levels of the HTL and ETL materials.

In a double heterostructure OLED, holes are injected from the HTL and electrons are injected from the ETL into the separate emissive layer, where the holes and electrons combine to form excitons.

Various compounds have been used as HTL materials or ETL materials. HTL materials mostly consist of triaryl amines in various forms which show high hole mobilities (˜10⁻³ cm²/Vs). There is somewhat more variety in the ETLs used in OLEDs. Aluminum tris(8-hydroxyquinolate) (Alq₃) is the most common ETL material, and others include oxidiazol, triazol, and triazine.

### SUMMARY OF THE INVENTION

We have now devised an improved electroluminescent device using an ETLs which hitherto has not been used for this purpose.

According to the invention there is provided an electroluminescent device which comprises
(i) a first electrode;
(ii) a layer of an organic electroluminescent material;
(iii) a layer of an electron transporting material selected from quinolates of transition metals in a four valent or five valent state and a dopant; and
(iv) a second electrode.

Doped zirconium quinolates have been disclosed as electroluminescent materials in Patent Application WO 2002/058913 the contents of which are included by reference but hitherto have not been used as electron transporting materials.

### DESCRIPTION OF PREFERRED FEATURES

### First and Second Electrodes; Device Features

The first electrode is preferably a transparent substrate such as a conductive glass or plastic material which acts as the anode; preferred substrates are conductive glasses such as indium tin oxide coated glass, but any glass which is conductive or has a conductive layer such as a metal or conductive polymer can be used. Conductive polymers and conductive polymer coated glass or plastics materials can also be used as the substrate.

The devices of the present invention can be used as displays in video displays, mobile telephones, portable computers and any other application where an electronically controlled visual image is used. The devices of the present invention can be used in both active and passive applications of such displays.

In known electroluminescent devices either one or both electrodes can be formed of silicon and the electroluminescent material and intervening layers of hole transporting and electron transporting materials can be formed as pixels on the silicon substrate. Preferably each pixel comprises at least one layer of an electroluminescent material and a (at least semi-) transparent electrode in contact with the organic layer on a side thereof remote from the substrate.

Preferably, the substrate is of crystalline silicon and the surface of the substrate may be polished or smoothed to produce a flat surface prior to the deposition of electrode, or electroluminescent compound. Alternatively a non-planarised silicon substrate can be coated with a layer of conducting polymer to provide a smooth, flat surface prior to deposition of further materials.

In one embodiment, each pixel comprises a metal electrode in contact with the substrate. Depending on the relative work functions of the metal and transparent electrodes, either may serve as the anode with the other constituting the cathode.

When the silicon substrate is the cathode an indium tin oxide coated glass can act as the anode and light is emitted through the anode. When the silicon substrate acts as the anode, the cathode can be formed of a transparent electrode which has a suitable work function; for example by an indium zinc oxide coated glass in which the indium zinc oxide has a low work function. The anode can have a transparent coating of a metal formed on it to give a suitable work function. These devices are sometimes referred to as top emitting devices or back emitting devices.

Preferably, the electrode also acts as a mirror behind each pixel and is either deposited on, or sunk into, the planarised surface of the substrate. However, there may alternatively be a light absorbing black layer adjacent to the substrate.

In still another embodiment, selective regions of a bottom conducting polymer layer are made non-conducting by exposure to a suitable aqueous solution allowing formation of arrays of conducting pixel pads which serve as the bottom contacts of the pixel electrodes.

### Optional Hole Transporting Layer

In some embodiments the first electrode can function as the anode and the second electrode can function as the cathode and preferably there is a layer of a hole transporting material between the anode and the layer of the electroluminescent compound.

The thickness of the hole transporting layer is preferably 20 nm to 200 nm. The hole transporting material can be any of the hole transporting materials used in electroluminescent devices.

The hole transporting material can be an amine complex such as poly (vinylcarbazole), N, N′-diphenyl-N, N′-bis (3-methylphenyl)-1,1′ -biphenyl -4,4′-diamine (TPD), an unsubstituted or substituted polymer of an amino substituted aromatic compound, a polyaniline, substituted polyanilines, polythiophenes, substituted polythiophenes, polysilanes etc. Examples of polyanilines are polymers of

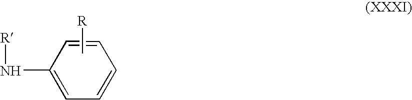

where R is in the ortho- or meta-position and is hydrogen, C1-18 alkyl, C1-6 alkoxy, amino, chloro, bromo, hydroxy or the group

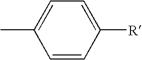

where R is alky or aryl and R′ is hydrogen, C1-6 alkyl or aryl with at least one other monomer of formula I above.

Or the hole transporting material can be a polyaniline; polyanilines which can be used in the present invention have the general formula

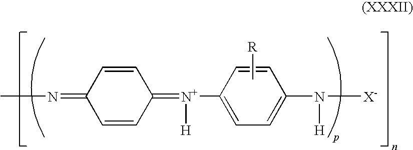

where p is from 1 to 10 and n is from 1 to 20, R is as defined above and X is an anion, preferably selected from Cl, Br, SO₄, BF₄, PF₆, H₂PO₃, H₂PO₄, arylsulphonate, arenedicarboxylate, polystyrenesulphonate, polyacrylate alkysulphonate, vinylsulphonate, vinylbenzene sulphonate, cellulose sulphonate, camphor sulphonates, cellulose sulphate or a perfluorinated polyanion.

Examples of arylsulphonates are p-toluenesulphonate, benzenesulphonate, 9,10-anthraquinone-sulphonate and anthracenesulphonate; an example of an arenedicarboxylate is phthalate and an example of arenecarboxylate is benzoate.

We have found that protonated polymers of the unsubstituted or substituted polymer of an amino substituted aromatic compound such as a polyaniline are difficult to evaporate or cannot be evaporated, however we have surprisingly found that if the unsubstituted or substituted polymer of an amino substituted aromatic compound is deprotonated, then it can be easily evaporated, i.e. the polymer is evaporable.

Preferably evaporable deprotonated polymers of unsubstituted or substituted polymer of an amino substituted aromatic compound are used. The de-protonated unsubstituted or substituted polymer of an amino substituted aromatic compound can be formed by deprotonating the polymer by treatment with an alkali such as ammonium hydroxide or an alkali metal hydroxide such as sodium hydroxide or potassium hydroxide.

The degree of protonation can be controlled by forming a protonated polyaniline and de-protonating. Methods of preparing polyanilines are described in the article by A. G. MacDiarmid and A. F. Epstein, Faraday Discussions, Chem Soc. 88 P319 1989.

The conductivity of the polyaniline is dependent on the degree of protonation with the maximum conductivity being when the degree of protonation is between 40 and 60%, for example, about 50%.

Preferably the polymer is substantially fully deprotonated.

A polyaniline can be formed of octamer units. i.e. p is four, e.g.

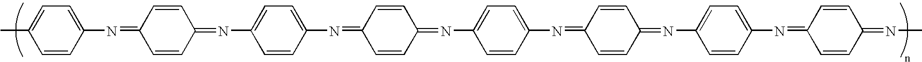

The polyanilines can have conductivities of the order of 1×10⁻² Siemen cm⁻¹ or higher.

The aromatic rings can be unsubstituted or substituted, e.g. by a C1 to 20 alkyl group such as ethyl.

The polyaniline can be a copolymer of aniline and preferred copolymers are the copolymers of aniline with o-anisidine, m-sulphanilic acid or o-aminophenol, or o-toluidine with o-aminophenol, o-ethylaniline, o-phenylene diamine or with amino anthracenes.

Other polymers of an amino substituted aromatic compound which can be used include substituted or unsubstituted polyaminonapthalenes, polyaminoanthracenes, polyaminophenanthrenes, etc. and polymers of any other condensed polyaromatic compound. Polyaminoanthracenes and methods of making them are disclosed in U.S. Pat. No. 6,153,726. The aromatic rings can be unsubstituted or substituted, e.g. by a group R as defined above.

Other hole transporting materials are conjugated polymers and the conjugated polymers which can be used can be any of the conjugated polymers disclosed or referred to in U.S. Pat. No. 5,807,627, PCT/WO90/13148 and PCT/WO92/03490.

The preferred conjugated polymers are poly (p-phenylenevinylene)-PPV and copolymers including PPV. Other preferred polymers are poly(2,5 dialkoxyphenylene vinylene) such as poly (2-methoxy-5-(2-methoxypentyloxy-1,4-phenylene vinylene), poly(2-methoxypentyloxy)-1,4-phenylenevinylene), poly(2-methoxy-5-(2-dodecyloxy-1,4-phenylenevinylene) and other poly(2,5 dialkoxyphenylenevinylenes) with at least one of the alkoxy groups being a long chain solubilising alkoxy group, poly fluorenes and oligofluorenes, polyphenylenes and oligophenylenes, polyanthracenes and oligo anthracenes, ploythiophenes and oligothiophenes.

In PPV the phenylene ring may optionally carry one or more substituents, e.g. each independently selected from alkyl, preferably methyl, alkoxy, preferably methoxy or ethoxy.

Any poly(arylenevinylene) including substituted derivatives thereof can be used and the phenylene ring in poly(p-phenylenevinylene) may be replaced by a fused ring system such as anthracene or naphthlyene ring and the number of vinylene groups in each polyphenylenevinylene moiety can be increased, e.g. up to 7 or higher.

The conjugated polymers can be made by the methods disclosed in U.S. Pat. No. 5,807,627, PCT/WO90/13148 and PCT/WO92/03490.

The polymers of an amino substituted aromatic compound such as polyanilines referred to above can also be used as buffer layers with or in conjunction with other hole transporting materials.

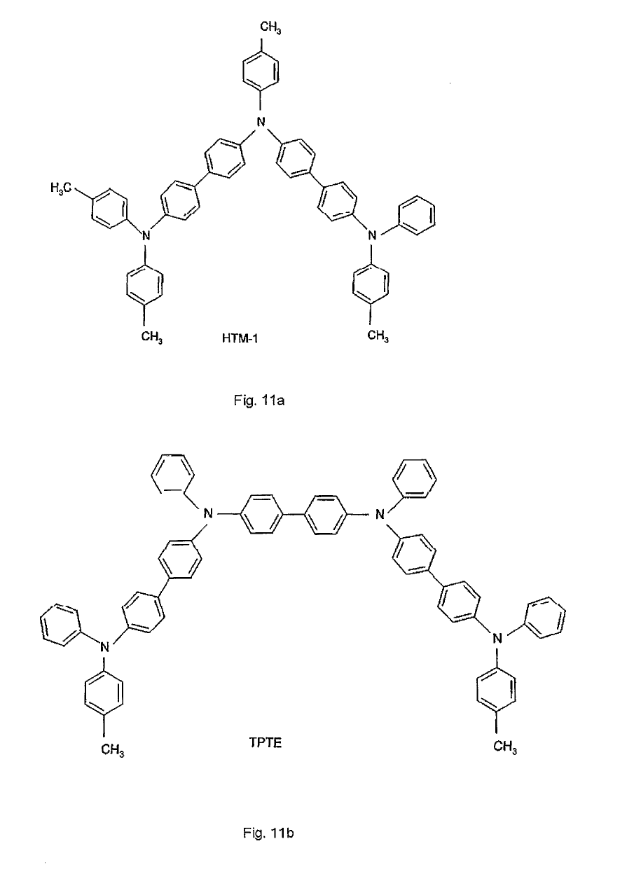

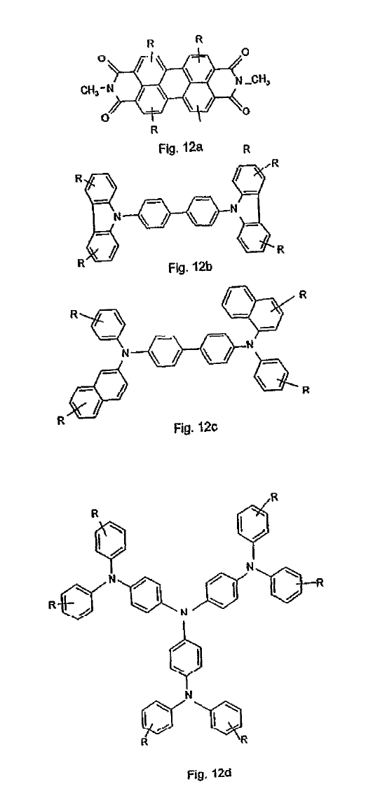

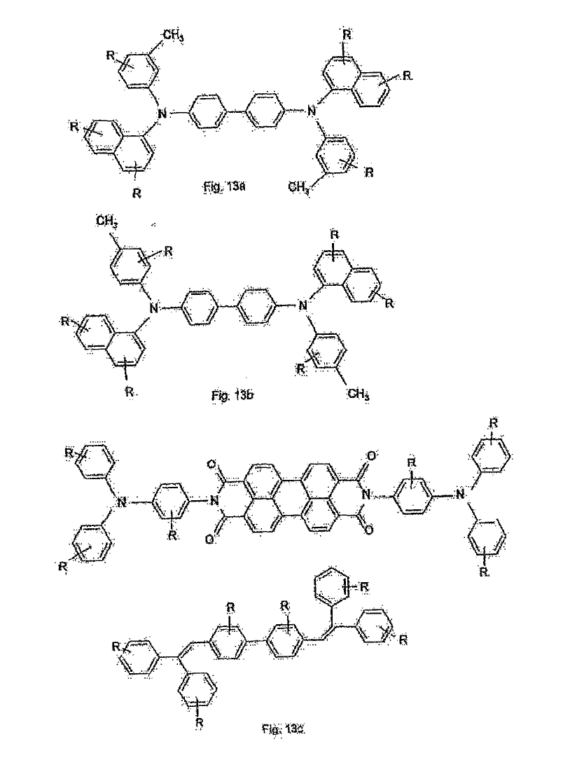

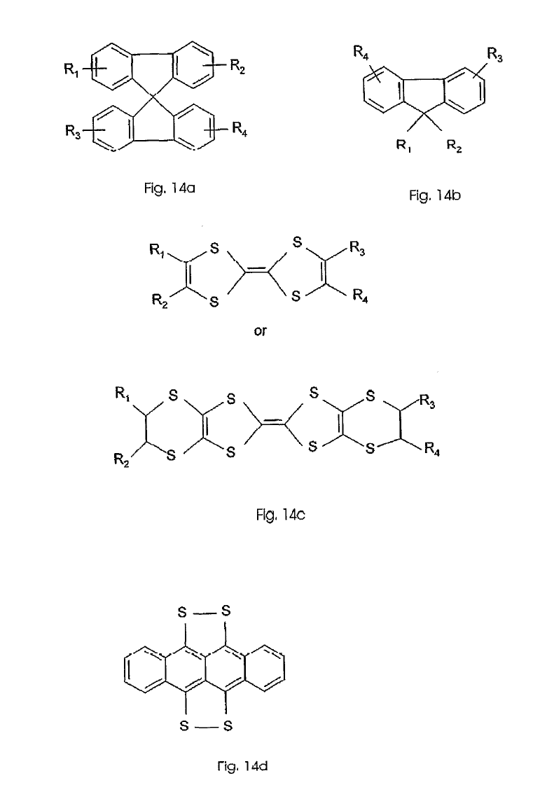

The structural formulae of some other hole transporting materials are shown in FIGS. 10 to 14 of the drawings, where R₁, R₂ and R₃ can be the same or different and are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; R₁, R₂ and R₃ can also form substituted and unsubstituted fused aromatic, heterocyclic and polycyclic ring structures and can be copolymerisable with a monomer, e.g. styrene. X is Se, S or O, Y can be hydrogen, substituted or unsubstituted hydrocarbyl groups, such as substituted and unsubstituted aromatic, heterocyclic and polycyclic ring structures, fluorine, fluorocarbons such as trifluoryl methyl groups, halogens such as fluorine or thiophenyl groups or nitrile.

Examples of R₁ and/or R₂ and/or R₃ include aliphatic, aromatic and heterocyclic alkoxy, aryloxy and carboxy groups, substituted and substituted phenyl, fluorophenyl, biphenyl, phenanthrene, anthracene, naphthyl and fluorene groups alkyl groups such as t-butyl, heterocyclic groups such as carbazole.

### Organic Electroluminescent Materials

Electroluminescent compounds which can be used in the present invention are of general formula (Lα)ₙM where M is a rare earth, lanthanide or an actinide, Lα is an organic complex and n is the valence state of M.

Other organic electroluminescent compounds which can be used in the present invention are of formula

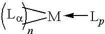

where Lα and Lp are organic ligands, M is a rare earth, transition metal, lanthanide or an actinide and n is the valence state of the metal M. The ligands Lα can be the same or different and there can be a plurality of ligands Lp which can be the same or different.

For example (L₁)(L₂)(L₃)(L . . . )M(Lp) where M is a rare earth, transition metal, lanthanide or an actinide and (L₁)(L₂)(L₃)(L . . . ) are the same or different organic complexes and (Lp) is a neutral ligand. The total charge of the ligands (L₁)(L₂)(L₃)(L . . . ) is equal to the valence state of the metal M. Where there are 3 groups Lα which corresponds to the III valence state of M the complex has the formula (L₁)(L₂)(L₃)M (Lp) and the different groups (L₁)(L₂)(L₃) may be the same or different.

Lp can be monodentate, bidentate or polydentate and there can be one or more ligands Lp.

Preferably M is metal ion having an unfilled inner shell and the preferred metals are selected from Sm(III), Eu(II), Eu(III), Tb(III), Dy(III), Yb(III), Lu(III), Gd (III), U(III), Tm(III), Ce (III), Pr(III), Nd(III), Pm(III), Ho(III), Er(III), Yb(III) and more preferably Eu(III), Tb(III), Dy(III), Gd (III), Er (III), Yt(III).

Further organic electroluminescent compounds which can be used in the present invention are of general formula (Lα)ₙM₁M₂ where M₁ is the same as M above, M₂ is a non rare earth metal, Lα is a as above and n is the combined valence state of M₁ and M₂. The complex can also comprise one or more neutral ligands Lp so the complex has the general formula (Lα)ₙ M₁ M₂ (Lp), where Lp is as above. The metal M₂ can be any metal which is not a rare earth, transition metal, lanthanide or an actinide. Examples of metals which can be used include lithium, sodium, potassium, rubidium, caesium, beryllium, magnesium, calcium, strontium, barium, copper (I), copper (II), silver, gold, zinc, cadmium, boron, aluminium, gallium, indium, germanium, tin (II), tin (IV), antimony (II), antimony (IV), lead (II), lead (IV) and metals of the first, second and third groups of transition metals in different valence states e.g. manganese, iron, ruthenium, osmium, cobalt, nickel, palladium(II), palladium(IV), platinum(II), platinum(IV), cadmium, chromium. titanium, vanadium, zirconium, tantalum, molybdenum, rhodium, iridium, titanium, niobium, scandium, yttrium.

For example, (L₁)(L₂)(L₃)(L . . . )M (Lp) where M is a rare earth, transition metal, lanthanide or an actinide and (L₁)(L₂)(L₃)(L . . . ) and (Lp) are the same or different organic complexes.

Further organometallic complexes which can be used in the present invention are binuclear, trinuclear and polynuclear organometallic complexes e.g. of formula (Lm)ₓM₁←M₂(Ln)_{y}e.g.

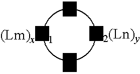

where L is a bridging ligand and where M₁ is a rare earth metal and M₂ is M₁ or a non rare earth metal, Lm and Ln are the same or different organic ligands Lα as defined above, x is the valence state of M₁ and y is the valence state of M₂.

In these complexes there can be a metal to metal bond or there can be one or more bridging ligands between M₁ and M₂ and the groups Lm and Ln can be the same or different.

By trinuclear is meant there are three rare earth metals joined by a metal to metal bond i.e. of formula

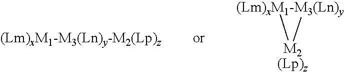

where M₁, M₂ and M₃ are the same or different rare earth metals and Lm, Ln and Lp are organic ligands Lα and x is the valence state of M₁, y is the valence state of M₂ and z is the valence state of M₃. Lp can be the same as Lm and Ln or different.

The rare earth metals and the non rare earth metals can be joined together by a metal to metal bond and/or via an intermediate bridging atom, ligand or molecular group.

For example the metals can be linked by bridging ligands e.g.

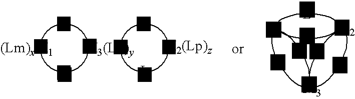

where L is a bridging ligand.

By polynuclear is meant there are more than three metals joined by metal to metal bonds and/or via intermediate ligands

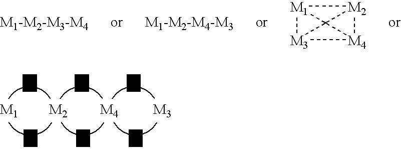

where M₁, M₂, M₃ and M4 are rare earth metals and L is a bridging ligand.

Preferably Lα is selected from β diketones such as those of formulae

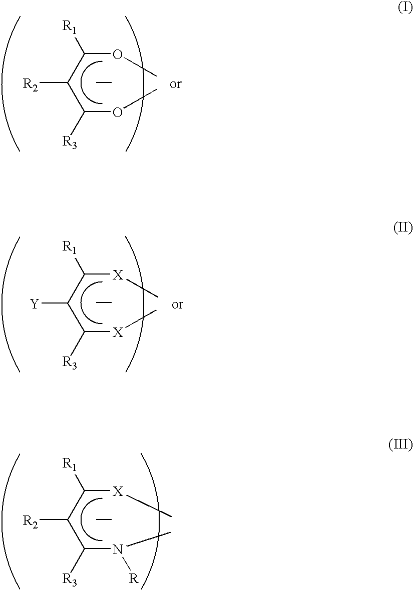

where R₁, R₂ and R₃ can be the same or different and are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; R₁, R₂ and R₃ can also form substituted and unsubstituted fused aromatic, heterocyclic and polycyclic ring structures and can be copolymerisable with a monomer e.g. styrene. X is Se, S or O, Y can be hydrogen, substituted or unsubstituted hydrocarbyl groups, such as substituted and unsubstituted aromatic, heterocyclic and polycyclic ring structures, fluorine, fluorocarbons such as trifluoryl methyl groups, halogens such as fluorine or thiophenyl groups or nitrile.

The beta diketones can be polymer substituted beta diketones and in the polymer, oligomer or dendrimer substituted β diketone the substituents group can be directly linked to the diketone or can be linked through one or more —CH₂ groups i.e.

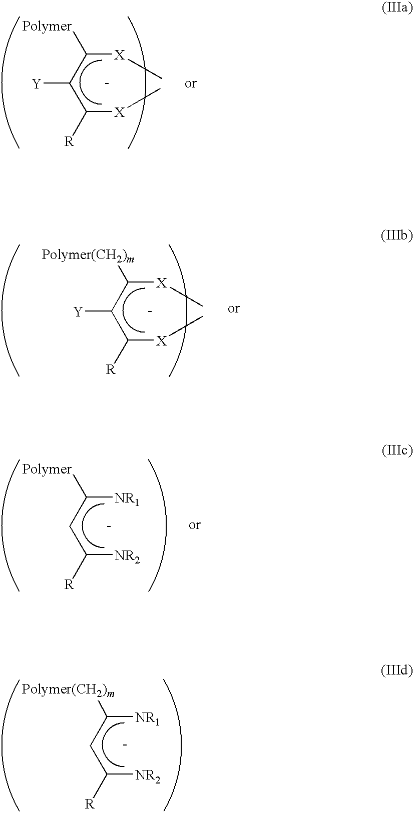

or through phenyl groups e.g.

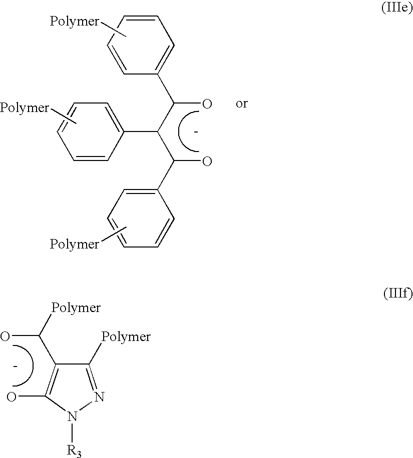

where “polymer” can be a polymer, an oligomer or a dendrimer, (there can be one or two substituted phenyl groups as well as three as shown in (IIIc)) and where R is selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups.

Examples of R₁ and/or R₂ and/or R₃ include aliphatic, aromatic and heterocyclic alkoxy, aryloxy and carboxy groups, substituted and substituted phenyl, fluorophenyl, biphenyl, phenanthrene, anthracene, naphthyl and fluorene groups alkyl groups such as t-butyl, heterocyclic groups such as carbazole.

Some of the different groups Lα may also be the same or different charged groups such as carboxylate groups so that the group L₁ can be as defined above and the groups L₂, L₃ . . . can be charged groups such as

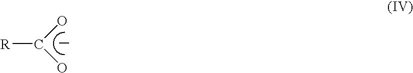

where R is R₁ as defined above or the groups L₁, L₂ can be as defined above and L₃. etc. are other charged groups.

R₁, R₂ and R₃ can also be

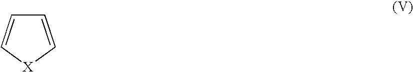

where X is O, S, Se or NH.

A preferred moiety R₁ is trifluoromethyl CF₃ and examples of such diketones are, banzoyltrifluoroacetone, p-chlorobenzoyltrifluoroacetone, p-bromotrifluoroacetone, p-phenyltrifluoroacetone, I-naphthoyltrifluoroacetone, 2-naphthoyltrifluoroacetone, 2-phenathoyltrifluoroacetone, 3-phenanthoyltrifluoroacetone, 9-anthroyltrifluoroacetonetrifluoroacetone, cinnamoyltrifluoroacetone, and 2-thenoyltrifluoroacetone.

The different groups Lα may be the same or different ligands of formulae

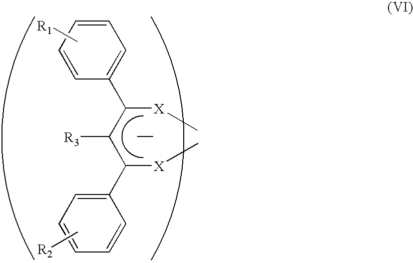

where X is O, S, or Se and R₁ R₂ and R₃ are as above.

The different groups Lα may be the same or different quinolate derivatives such as

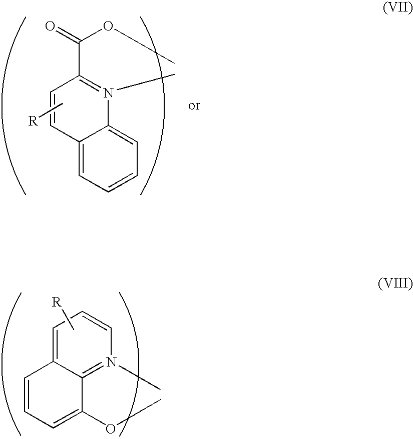

where R is hydrocarbyl, aliphatic, aromatic or heterocyclic carboxy, aryloxy, hydroxy or alkoxy e.g. the 8 hydroxy quinolate derivatives or

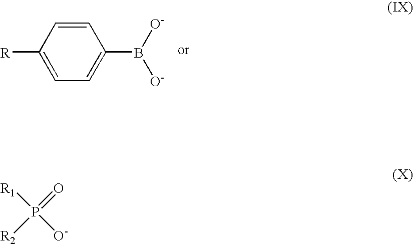

where R, R₁, and R₂ are as above or are H or F e.g. R₁ and R₂ are alkyl or alkoxy groups

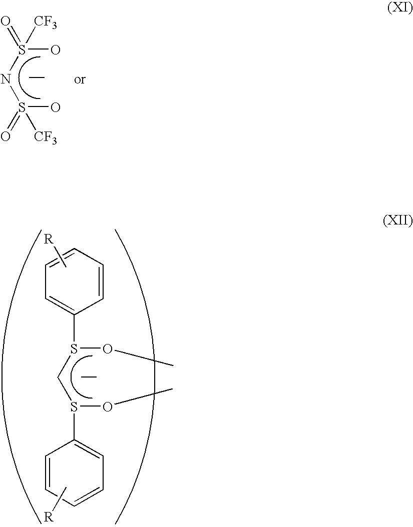

As stated above the different groups Lα may also be the same or different carboxylate groups e.g.

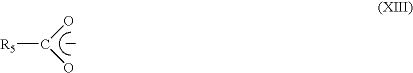

where R₅ is a substituted or unsubstituted aromatic, polycyclic or heterocyclic ring a polypyridyl group, R₅ can also be a 2-ethyl hexyl group so Lₙ is 2-ethylhexanoate or R₅ can be a chair structure so that Lₙ is 2-acetyl cyclohexanoate or Lα can be

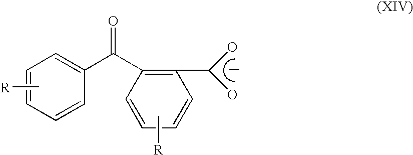

where R is as above e.g. alkyl, allenyl, amino or a fused ring such as a cyclic or polycyclic ring.

The different groups Lα may also be

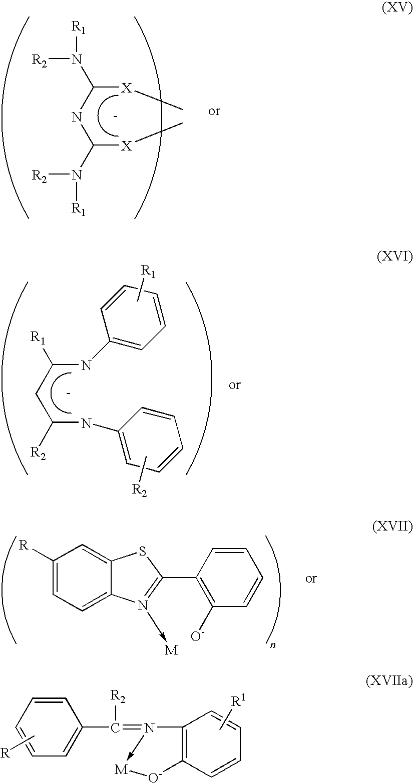

where R, R₁ and R₂ are as above.

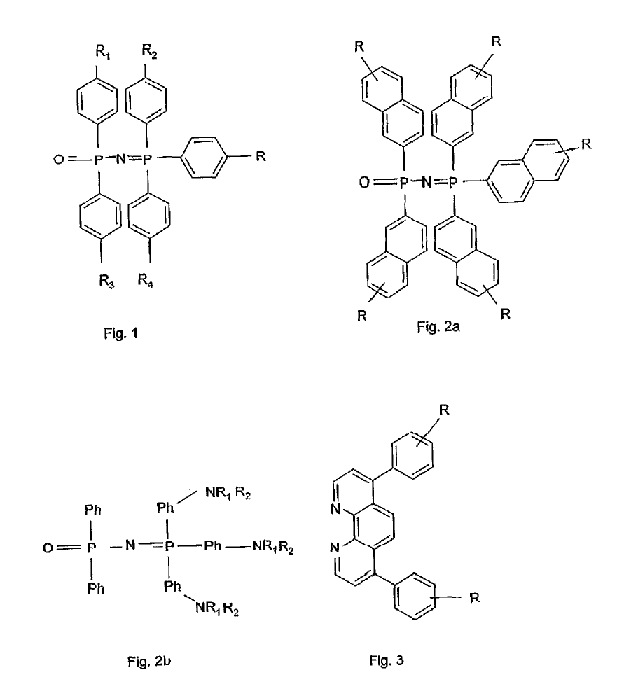

The groups L_{P} can be selected from

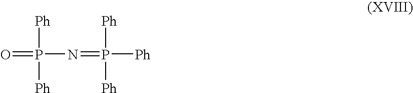

where each Ph which can be the same or different and can be a phenyl (OPNP) or a substituted phenyl group, other substituted or unsubstituted aromatic group, a substituted or unsubstituted heterocyclic or polycyclic group, a substituted or unsubstituted fused aromatic group such as a naphthyl, anthracene, phenanthrene or pyrene group. The substituents can be for example an alkyl, aralkyl, alkoxy, aromatic, heterocyclic, polycyclic group, halogen such as fluorine, cyano, amino. Substituted amino etc. Examples are given in FIGS. 1 and 2 of the drawings where R, R₁, R₂, R₃ and R₄ can be the same or different and are selected from hydrogen, hydrocarbyl groups, substituted and unsubstituted aromatic, heterocyclic and polycyclic ring structures, fluorocarbons such as trifluoryl methyl groups, halogens such as fluorine or thiophenyl groups; R, R₁, R₂, R₃ and R₄ can also form substituted and unsubstituted fused aromatic, heterocyclic and polycyclic ring structures and can be copolymerisable with a monomer e.g. styrene. R, R₁, R₂, R₃ and R4 can also be unsaturated alkylene groups such as vinyl groups or groups

—C—CH₂═CH₂—R

where R is as above.

Lₚ can also be compounds of formulae

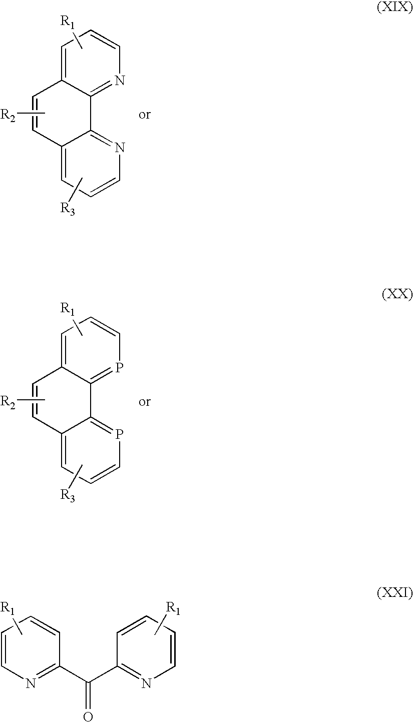

where R₁, R₂ and R₃ are as referred to above, for example bathophen shown in FIG. 3 of the drawings in which R is as above or

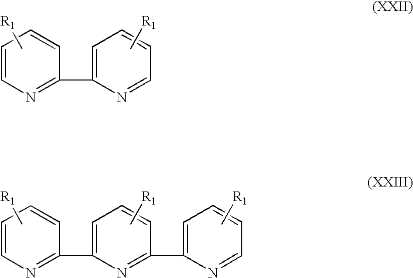

where R₁, R₂ and R₃ are as referred to above. Lₚ can also be

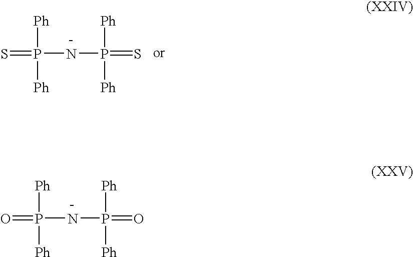

where Ph is as above.

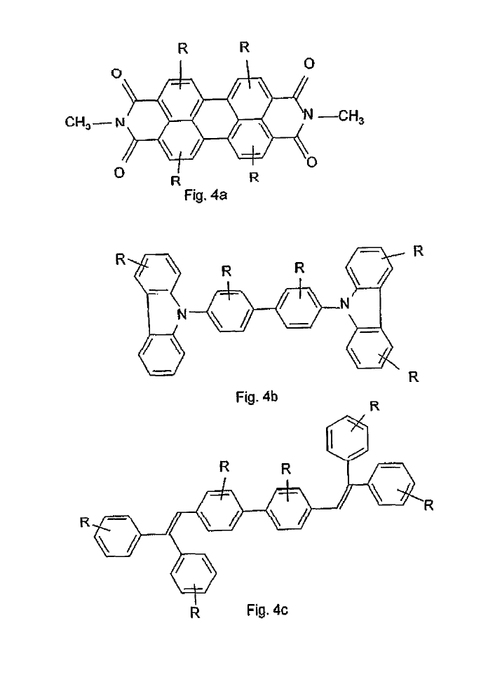

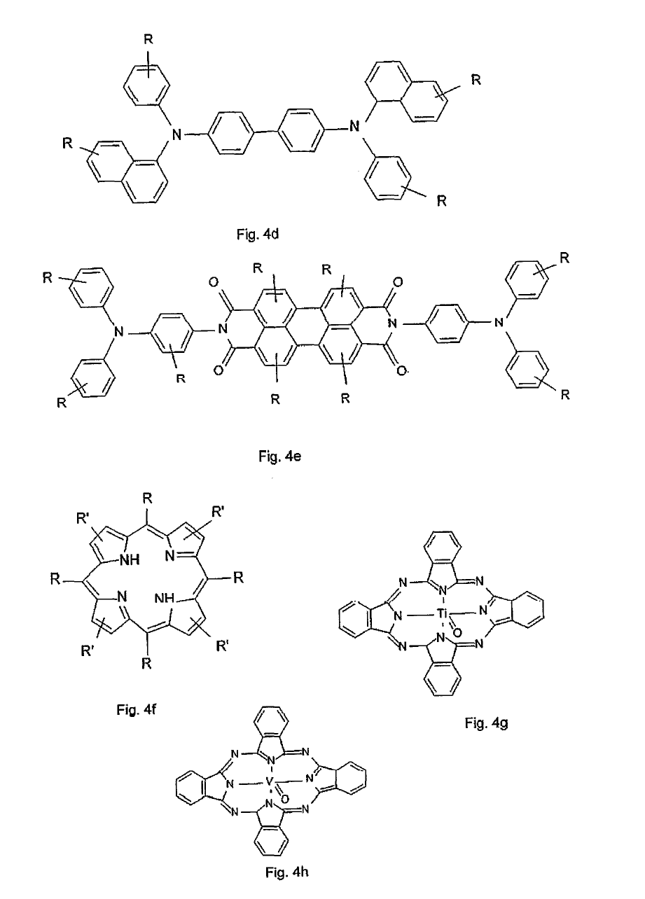

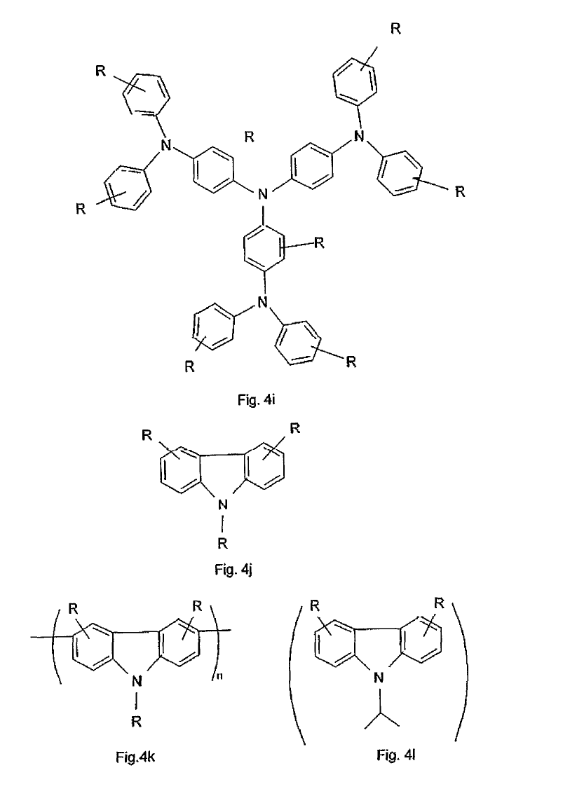

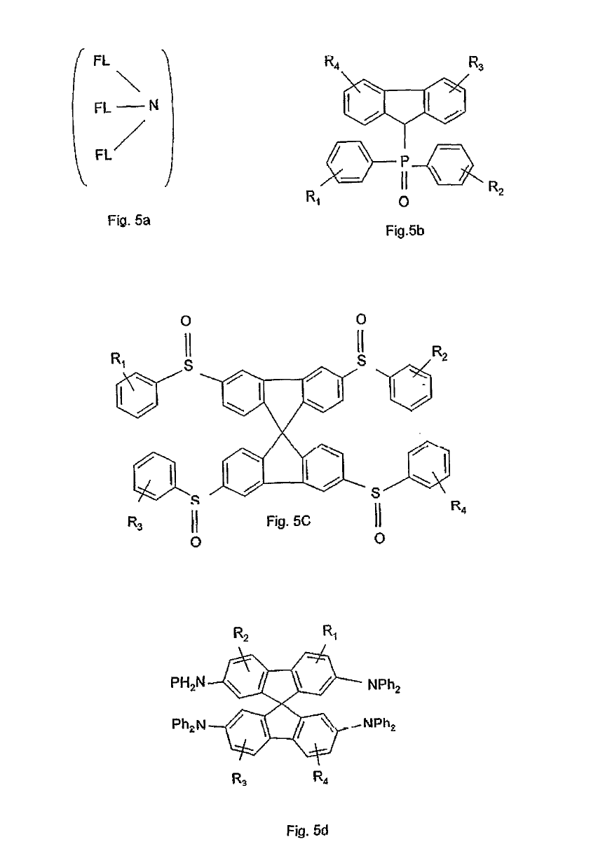

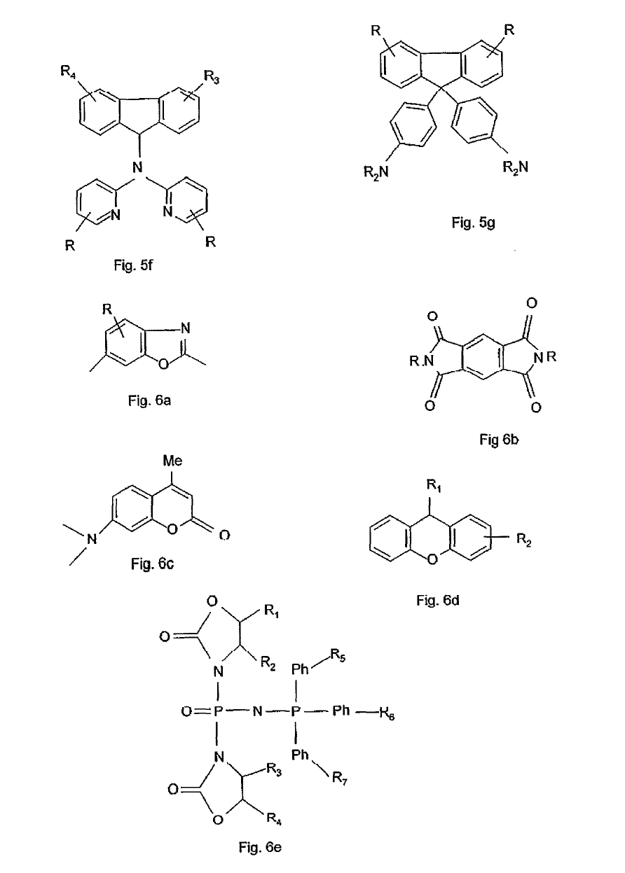

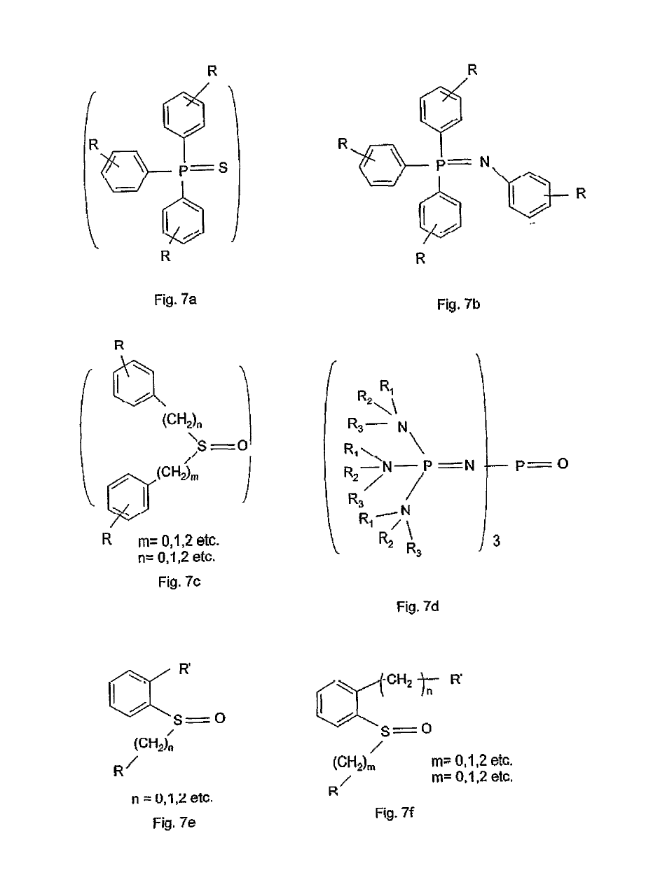

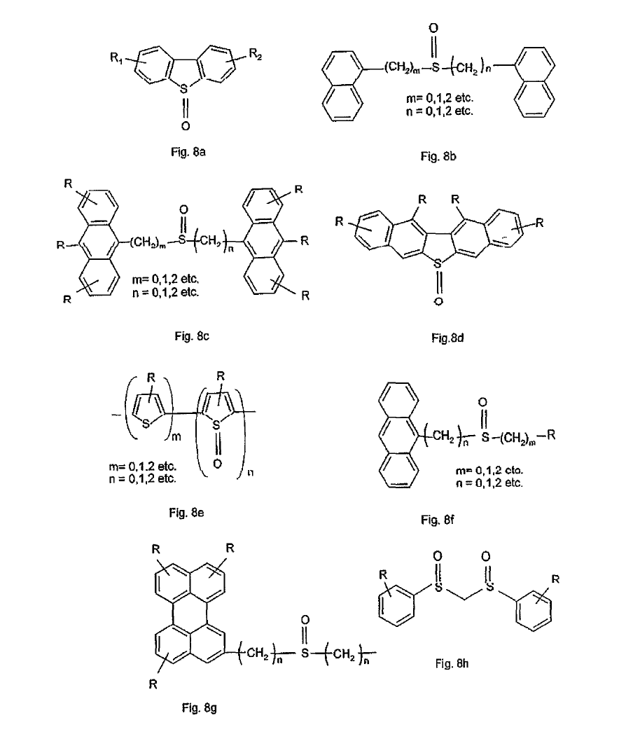

Other examples of Lp chelates are as shown in FIG. 4 and fluorene and fluorene derivatives e.g. as shown in FIG. 5 and compounds of formulae as shown in FIGS. 6 to 8.

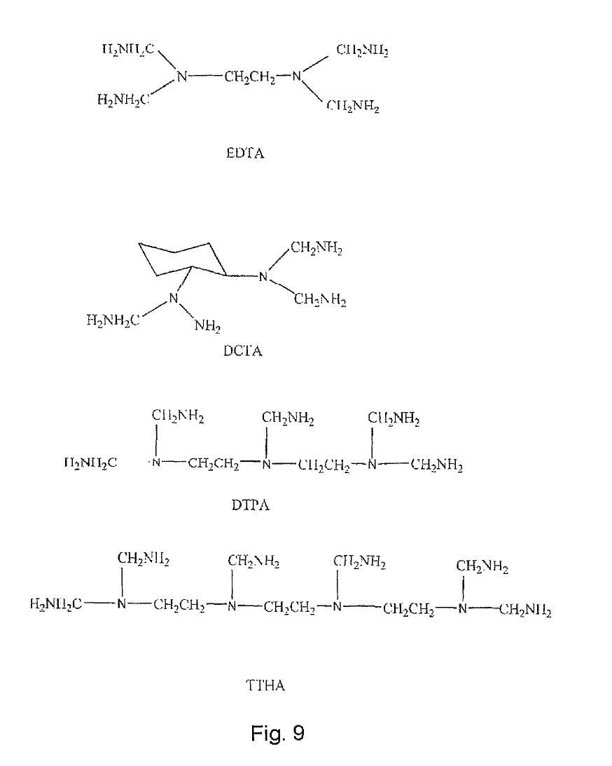

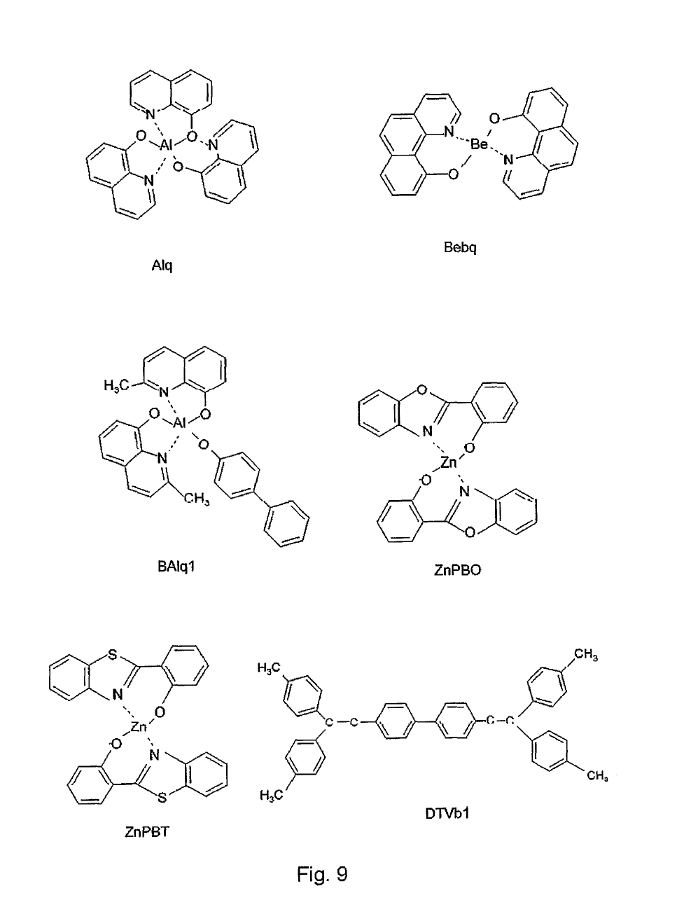

Specific examples of Lα and Lp are tripyridyl and TMHD, and TMHD complexes, α, α′, α″ tripyridyl, crown ethers, cyclans, cryptans phthalocyanans, porphoryins ethylene diamine tetramine (EDTA), DCTA, DTPA and TTHA, where TMHD is 2,2,6,6-tetramethyl-3,5-heptanedionato and OPNP is diphenylphosphonimide triphenyl phosphorane. The formulae of the polyamines are shown in FIG. 9.

Other organic electroluminescent materials which can be used include:-
(1) metal quinolates such as lithium quinolate, and non rare earth metal complexes such as aluminium, magnesium, zinc and scandium complexes such as complexes of β-diketones e.g. Tris-(1,3-diphenyl-1-3-propanedione) (DBM) and suitable metal complexes are Al(DBM)₃, Zn(DBM)₂ and Mg(DBM)₂, Sc(DBM)₃ etc.
(2) the metal complexes of formula

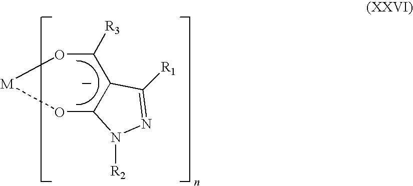

where M is a metal other than a rare earth, a transition metal, a lanthanide or an actinide; n is the valency of M; R₁, R₂ and R₃ which may be the same or different are selected from hydrogen, hydrocarbyl groups, substituted and unsubstituted aliphatic groups substituted and unsubstituted aromatic, heterocyclic and polycyclic ring structures, fluorocarbons such as trifluoryl methyl groups, halogens such as fluorine or thiophenyl groups or nitrile; R₁, and R₃ can also be form ring structures and R₁, R₂ and R₃ can be copolymerisable with a monomer e.g. styrene. Preferably M is aluminium and R₃ is a phenyl or substituted phenyl group.
(3) diiridium compounds of formula

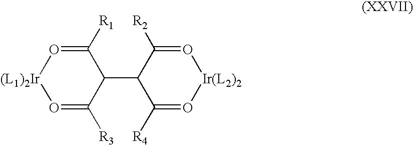

where R₁, R₂, R₃ and R4 can be the same or different and are selected from hydrogen, and substituted and unsubstituted hydrocarbyl groups.
(4) boron compounds of formula

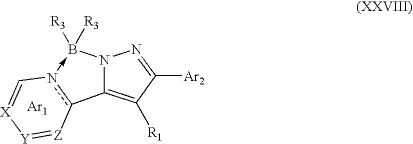

wherein Ar₁ represents a group selected from unsubstituted and substituted monocyclic or polycyclic heteroaryls having a ring nitrogen atom for forming a coordination bond to boron as indicated and optionally one or more additional ring nitrogen atoms subject to the proviso that nitrogen atoms do not occur in adjacent positions, X and Z being selected from carbon and nitrogen and Y being carbon or optionally nitrogen if neither of X and Z is nitrogen, said substituents if present being selected from substituted and unsubstituted hydrocarbyl, substituted and unsubstituted hydrocarbyloxy, fluorocarbon, halo, nitrile, amino alkylamino, dialkylamino or thiophenyl;

Ar₂ represents a group selected from monocyclic and polycyclic aryl and heteroaryl optionally substituted with one or more substituents selected from substituted and unsubstituted hydrocarbyl, substituted and unsubstituted hydrocarbyloxy, fluorocarbon, halo, nitrile, amino, alkylamino, dialkylamino and thiophenyl;

R₁ represents hydrogen or a group selected from substituted and unsubstituted hydrocarbyl, halohydrocarhyl and halo; and

R₂ and R₃ each independently represent a moiety selected from alkyl, cycloalkyl, cycloalkylalkyl, haloalkyl, halo and monocyclic, polycyclic, aryl, hetercaryl, aralkyl and heteroaralkyl optionally substituted with one or more of a moiety selected from alkyl, cycloalkyl, cycloalkylalkyl, haloalkyl, aryl, aralkyl, alkoxy, aryloxy, halo, nitric, amino, alkylamino and dialkylamino.
(5) compounds of formula

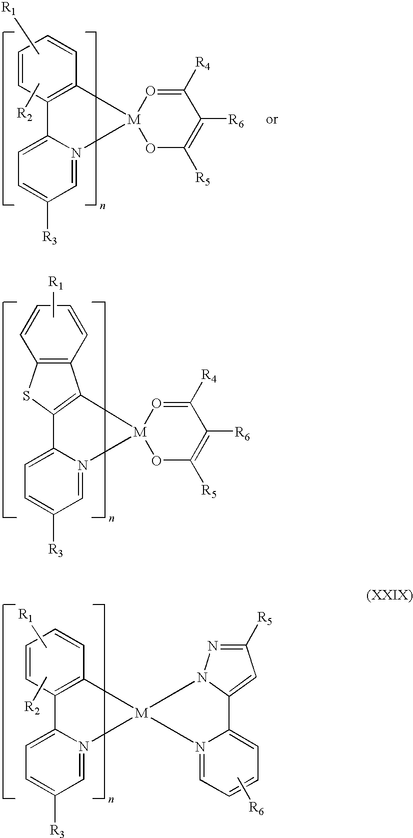

where R₁, R₂, R₃ , R_{4,} R₅ and R₆ can be the same or different and are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; R₁, R₂ and R₃ can also form substituted and unsubstituted fused aromatic, heterocyclic and polycyclic ring structures and can be copolymerisable with a monomer, e.g. styrene, and where R_{4,} and R₅ can be the same or different and are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; R₁, R₂ and R₃ can also form substituted and unsubstituted fused aromatic, heterocyclic and polycyclic ring structures and can be copolymerisable with a monomer, M is ruthenium, rhodium, palladium, osmium, iridium or platinum and n+2 is the valency of M.
(6) electroluminescent compounds of general formula

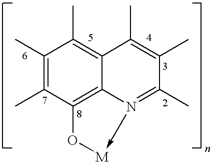

where M is the metal, n is the valency state of the metal and the where the substituents are the same or different in the 2, 3, 4, 5, 6 and 7 positions and are preferably selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine; thiophenyl groups; cyano group; substituted and unsubstituted hydrocarbyl groups such as substituted and unsubstituted aliphatic groups, substituted and unsubstituted aliphatic groups.

Preferably M is titanium, zirconium, hafnium in the four valent state or vanadium, niobium or tantulum in the five valency state The preferred quinolates are the 2-methyl and the 5- methyl quinolates.

Metal quinolates can be synthesised by the reaction of a metal compound such as a salt, ethoxide or alkyl 8-hydroxyquinoline in accordance with well known methods. For electroluminescent materials the reaction preferably takes place in a nitrile solvent such as acetonitrile, phenyl nitrile, tolyl nitrile, etc.
(7) electroluminescent compounds of formula

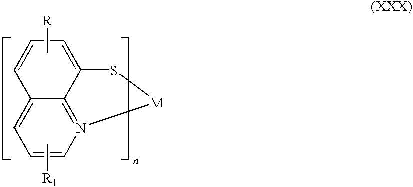

where M is a metal; n is the valency of M; R and R₁ which can be the same or different are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine; thiophenyl groups; cyano group; substituted and unsubstituted hydrocarbyl groups such as substituted and unsubstituted aliphatic groups, substituted and unsubstituted aliphatic groups.

M is titanium, zirconium, hafnium in the four valent state or vanadium, niobium or tantulum in the five valency state and (L₁), (L₂), (L₃) (L₄) and (L₅) can be the same or different and can form fused cyclic, heterocyclic, aromatic or substituted aromatic rings.

### The Electron Transporting Material

The thickness of the doped metal quinolate ETL layer is preferably from 2 to 100 nm and more preferably from 10 to 50 nm.

In the quinolates used herein, preferably the metal is a transition metal such as titanium, zirconium or hafnium in the four valency state or vanadium, niobium or tantulum in the five valency state of general formula

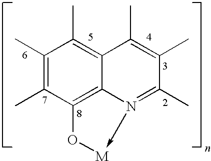

where M is the metal, n is the valency state of the metal and where the substituents are the same or different in the 2, 3, 4, 5, 6 and 7 positions and are preferably selected from alky, alkoxy, aryl, aryloxy, sulphonic acids, esters, carboxylic acids, amino and amido groups or are aromatic, polycyclic or heterocyclic groups. The preferred quinolates are the 2-methyl and the 5- methyl quinolates.

Metal quinolates can be synthesised by the reaction of a metal compound such as a salt, ethoxide or alkyl 8-hydroxyquinoline in accordance with well known methods. For electroluminescent materials the reaction preferably takes place in a nitrile solvent such as acetonitrile, phenyl nitrile, tolyl nitrile, etc.

The electroluminescent compound is doped with a minor amount of a fluorescent material as a dopant, preferably in an amount of 5 to 15% of the doped mixture.

Useful fluorescent materials are those capable of being blended with the organo metallic complex and fabricated into thin films satisfying the thickness ranges described above forming the luminescent zones of the EL devices of this invention. While crystalline organo metallic complexes do not lend themselves to thin film formation, the limited amounts of fluorescent materials present in the organo metallic complex materials permits the use of fluorescent materials which alone are incapable of thin film formation. Preferred fluorescent materials are those which form a common phase with the organo metallic complex material. Fluorescent dyes constitute a preferred class of fluorescent materials, since dyes lend themselves to molecular level distribution in the organo metallic complex. Although any convenient technique for dispersing the fluorescent dyes in the organo metallic complexes can be undertaken, preferred fluorescent dyes are those which can be vacuum vapour deposited along with the organo metallic complex materials. Assuming other criteria, noted above, are satisfied, fluorescent laser dyes are recognized to be particularly useful fluorescent materials for use in the organic EL devices of this invention. Dopants which can be used include diphenylacridine, coumarins, perylene and their derivatives.

Useful fluorescent dopants are disclosed in U.S. Pat. No. 4,769,292 the contents of which are included by reference.

The preferred dopants are coumarins such as those of formula

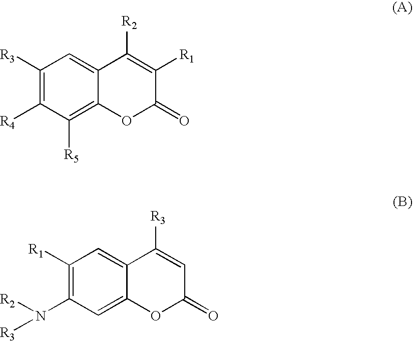

where R₁ is chosen from the group consisting of hydrogen, carboxy, alkanoyl, alkoxycarbonyl, cyano, aryl, and a heterocylic aromatic group, R₂ is chosen from the group consisting of hydrogen, alkyl, haloalkyl, carboxy, alkanoyl, and alkoxycarbonyl, R₃ is chosen from the group consisting of hydrogen and alkyl, R₄ is an amino group, and R₅ is hydrogen, or R₁ or R₂ together form a fused carbocyclic ring, and/or the amino group forming R⁴ completes with at least one of R⁴ and R⁶ a fused ring.

The alkyl moieties in each instance contain from 1 to 5 carbon atoms, preferably 1 to 3 carbon atoms. The aryl moieties are preferably phenyl groups. The fused carbocyclic rings are preferably five, six or seven membered rings. The heterocyclic aromatic groups contain 5 or 6 membered heterocyclic rings containing carbon atoms and one or two heteroatoms chosen from the group consisting of oxygen, sulphur, and nitrogen. The amino group can be a primary, secondary, or tertiary amino group. When the amino nitrogen completes a fused ring with an adjacent substituent, the ring is preferably a five or six membered ring. For example, R⁴ can take the form of a pyran ring when the nitrogen atom forms a single ring with one adjacent substituent (R³ or R⁵) or a julolidine ring (including the fused benzo ring of the coumarin) when the nitrogen atom forms rings with both adjacent substituents R₃ and R₅.

The following are illustrative fluorescent coumarin dyes known to be useful as laser dyes: FD-1 7-Diethylamino-4-methylcoumarin, FD-2 4,6-Dimethyl-7-ethylaminocoumarin, FD-3 4-Methylumbelliferone, FD-4 3-(2′-Benzothiazolyl)-7-diethylaminocoumarin, FD-5 3-(2′-Benzimidazolyl)-7-N,N-diethylaminocoumarin, FD-6 7-Amino-3-phenylcoumarin, FD-7 3-(2′-N-Methylbenzimidazolyl)-7-N,Ndiethylaminocoumarin, FD-8 7-Diethylamino-4-trifluoromethylcoumarin, FD-9 2,3,5,6-1H,4H-Tetrahydro-8-methylquinolazino[9,9a,1-gh]coumarin, FD-10 Cyclopenta[c]julolindino[9,10-3]-11H-pyran-11-one, FD-11 7-Amino-4-methylcoumarin, FD-12 7-Dimethylaminocyclopenta[c]coumarin, FD-13 7-Amino-4-trifluoromethylcoumarin, FD-14 7-Dimethylamino-4-trifluoromethylcoumarin, FD-15 1,2,4,5,3H,6H, 10H-Tetrahydro-8-trifluoromethyl[1]benzopyrano[9,9a,1-gh]quinolizin-10-one, FD-16 4-Methyl-7-(sulfomethylamino)coumarin sodium salt, FD-17 7-Ethylamino-6-methyl-4-trifluoromethylcoumarin, FD-18 7-Dimethylamino-4-methylcoumarin, FD-19 1,2,4,5,3H,6H, 10H-Tetrahydro-carbethoxy[1]benzopyrano[9,9a, 1-gh]quinolizino-10-one, FD-20 9-Acetyl-1,2,4,5,3H,6H, 10H-tetrahydro[1]benzopyrano[9,9a,1-gh]quinolizino-10-one, FD-21 9-Cyano-1,2,4,5,3H,6H, 10H-tetrahydro[1]benzopyrano[9,9a,1-gh]quinolizino-10-one, FD22 9-(t-Butoxycarbonyl)-1,2,4,5,3H,6H, 10H-tetrahyro[1]benzopyrano[9,9a,1-gh]quinolizino-10-one, FD-23 4-Methylpiperidino[3,2-g]coumarin, FD-24 4-Trifluoromethylpiperidino[3,2-g]coumarin, FD-25 9-Carboxy-1,2,4,5,3H,6H,10H-tetrahydro[1]benzopyrano[9,9a,1-gh]quinolizino-10-one, FD-26 N-Ethyl-4-trifluoromethylpiperidino[3,2-g].

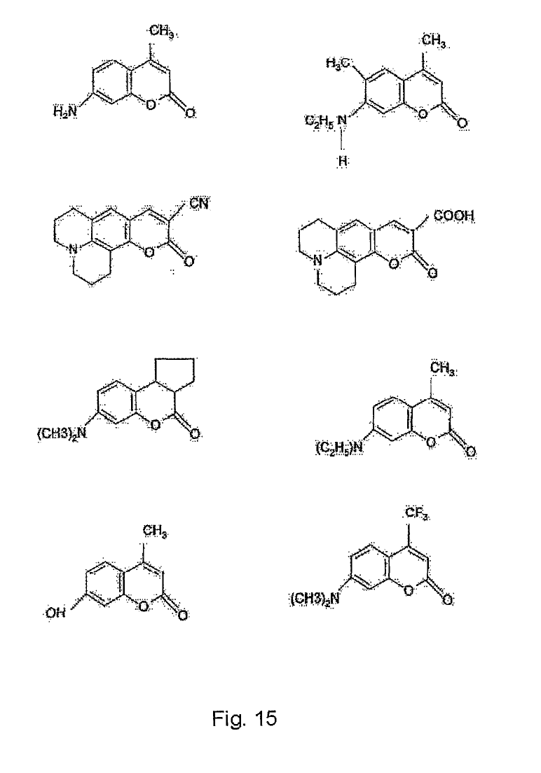

Other examples of coumarins are given in FIG. 15 of the drawings.

Other dopants include salts of bis benzene sulphonic acid such as

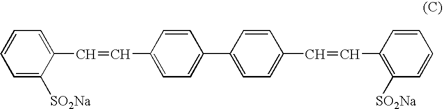

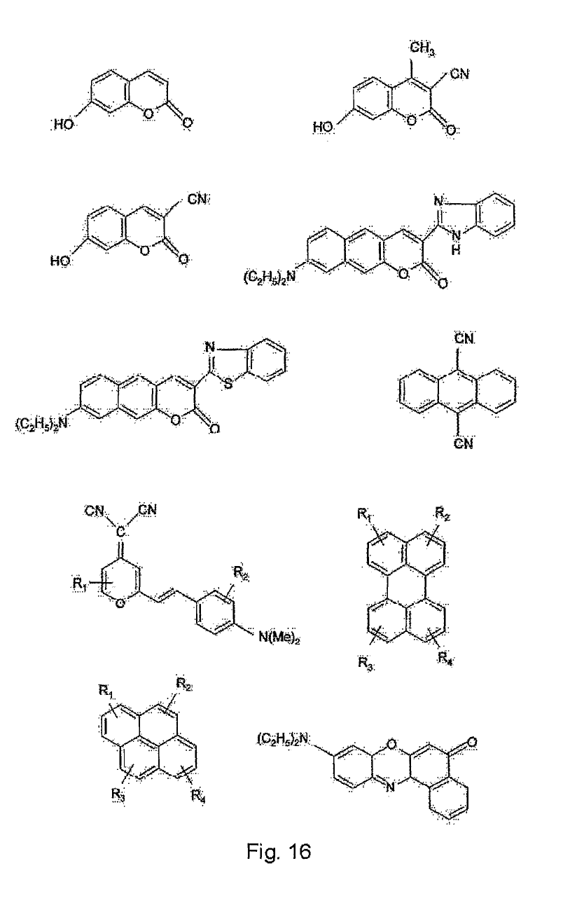

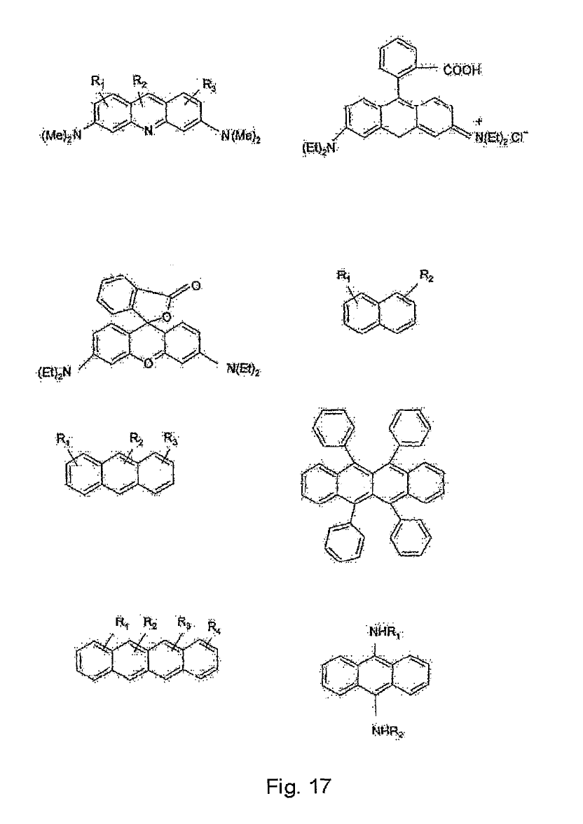

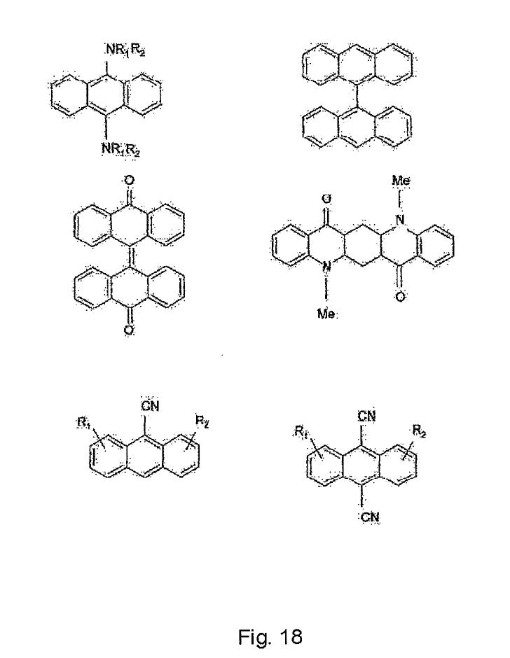

and perylene and perylene derivatives and dopants of the formulae of FIGS. 16 to 18 of the drawings where R₁, R₂, R₃ and R₄ are R, R₁, R₂, R₃ and R₄ can be the same or different and are selected from hydrogen, hydrocarbyl groups, substituted and unsubstituted aromatic, heterocyclic and polycyclic ring structures, fluorocarbons such as trifluoryl methyl groups, halogens such as fluorine or thiophenyl groups; R, R₁, R₂, R₃ and R₄ can also form substituted and unsubstituted fused aromatic, heterocyclic and polycyclic ring structures and can be copolymerisable with a monomer e.g. styrene. R, R₁, R₂, R₃ and R₄ can also be unsaturated alkylene groups such as vinyl groups or groups

—C—CH₂═CH₂—R

where R is as above.

Other dopants are dyes such as the fluorescent 4-dicyanomethylene-4H-pyrans and 4-dicyanomethylene-4H-thiopyrans, e.g. the fluorescent dicyanomethylenepyran and thiopyran dyes.

Useful fluorescent dyes can also be selected from among known polymethine dyes, which include the cyanines, merocyanines, complex cyanines and merocyanines (i.e. tri-, tetra- and poly-nuclear cyanines and merocyanincs), oxonols, hemioxonols, styryls, merostyryls, and streptocyanines.

The cyanine dyes include, joined by a methine linkage, two basic heterocyclic nuclei, such as azolium or azinium nuclei, for example, those derived from pyridinium, quinolinium, isoquinolinium, oxazolium, thiazolium, selenazolium, indazolium, pyrazolium, pyrrolium, indolium, 3H-indolium, imidazolium, oxadiazolium, thiadioxazolium, benzoxazolium, benzothiazolium, benzoselenazolium, benzotellurazolium, benzimidazolium, 3H- or 1H-benzoindolium, naphthoxazolium, naphthothiazolium, naphthoselenazolium, naphthotellurazolium, carbazolium, pyrrolopyridinium, phenanthrothiazolium, and acenaphthothiazolium quaternary salts.

Other useful classes of fluorescent dyes are 4-oxo-4H-benz-[d,e]anthracenes and pyrylium, thiapyrylium, selenapyrylium, and telluropyrylium dyes.

In another electroluminescent structure the electroluminescent layer is formed of layers of two electroluminescent organic complexes in which the band gap of the second electroluminescent metal complex or organo metallic complex such as a gadolinium or cerium complex is larger than the band gap of the first electroluminescent metal complex or organo metallic complex such as a europium or terbium complex.

How the invention may be put into effect will now be described, by way of example only, with reference to the following non-limitative Examples.

### EXAMPLE 1

### Device Structure

A pre-etched ITO coated glass piece (10×10 cm²) was used. The device was fabricated by sequentially forming layers on the ITO, by vacuum evaporation using a Solciet Machine, ULVAC Ltd., Chigacki, Japan. The active area of each pixel was 3 mm by 3 mm.

The coated electrodes were stored in a vacuum desiccator over a molecular sieve and phosphorous pentoxide until they were loaded into a vacuum coater (Edwards, 10⁻⁶ torr) and aluminium top contacts made. The devices were then kept in a vacuum desiccator until the electroluminescence studies were performed.

The ITO electrode was always connected to the positive terminal. The current vs. voltage studies were carried out on a computer controlled Keithly 2400 source meter.

### EXAMPLE 2

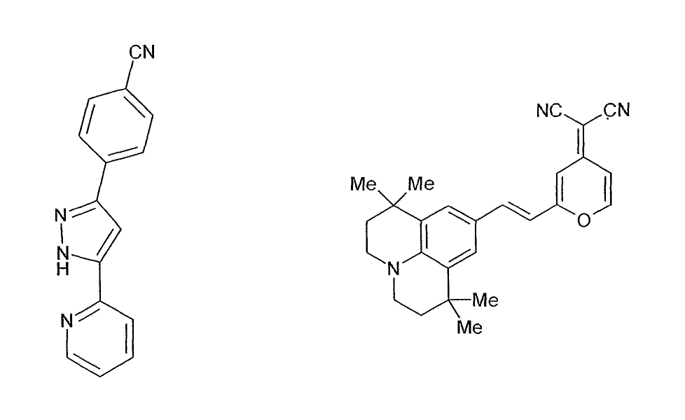

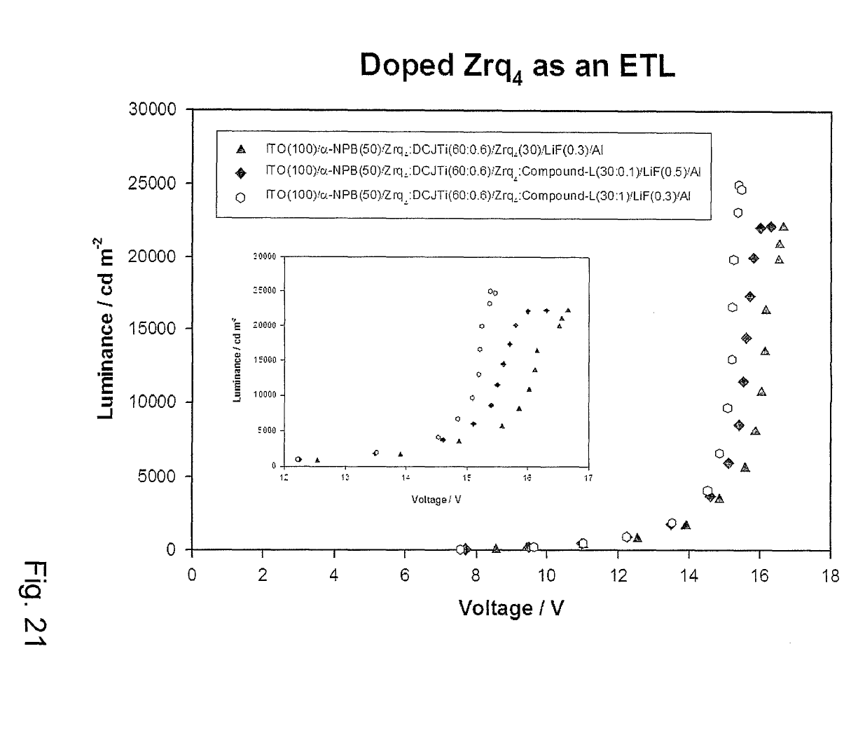

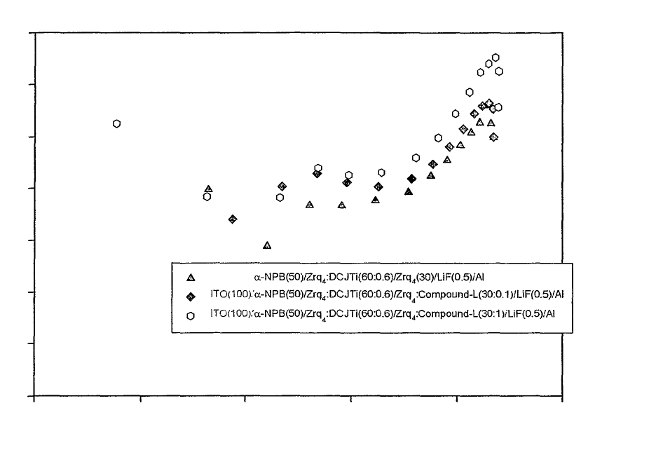

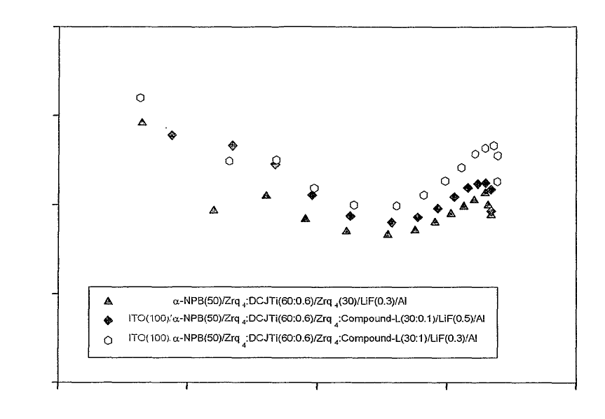

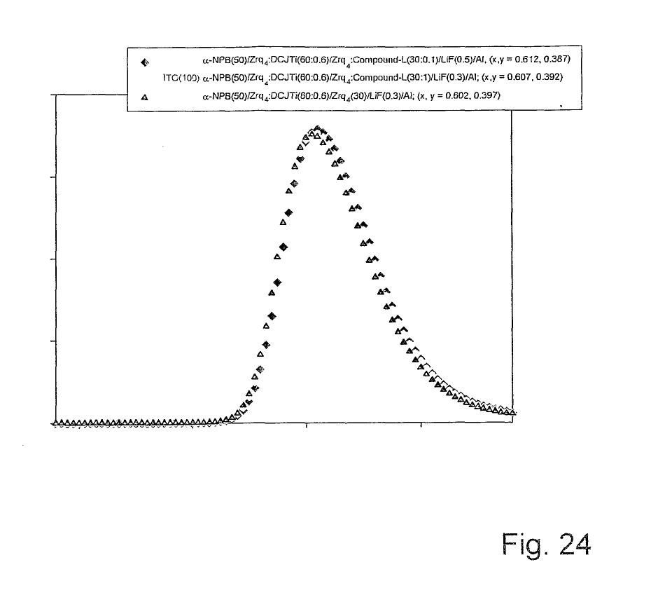

Two devices were formed by the method of Example 1 using lithium fluoride and lithium quinolate as a cathode layer; the devices consisted of
(i) ITO(100)/α-NPB(50)/Zrq₄:DCJTi (60:0.6)/Zrq₄ (30)/LiF(0.3)/Al
(ii) ITO(100)/α-NPB(50)/Zrq₄:DCJTi (60:0.6)/Zrq₄: Compound L (30:0.1)/LiF(0.5)/Al
(iii) ITO(100)/α-NPB(50)/Zrq₄:DCJTi (60:0.6)/Zrq₄: Compound L (30:1)/LiF(0.3)/Al. where α-NPB is as shown in FIG. 16; compounds DCJTi and L are as shown in FIGS. 19 and 20 (see also below); Zrq₄ is zirconium quinolate; LiF is lithium fluoride; Liq is lithium quinolate. The performance of the devices was measured and the results shown in FIGS. 21 to 24.

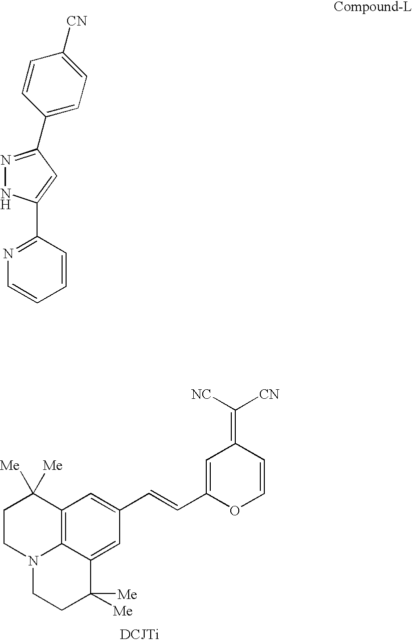

1.-39. (canceled)

40. An electroluminescent device which comprises
(i) a first electrode which is an anode;
(ii) a second electrode which is a cathode;
(iii) a layer of an organic electroluminescent material located between said first and second electrodes; and,
(iv) a layer of an electron transport material comprising a first quinolate selected from quinolates of transition metals in a four valent or five valent state together with a dopant located between said first and second electrodes.

41. The device of claim 40, wherein there is a layer of hole transport material between the first electrode and the layer of electroluminescent material.

42. The device of claim 41, wherein the hole transport material comprises an aromatic amine.

43. The device of claim 42, wherein the aromatic amine is selected from the group consisting of: 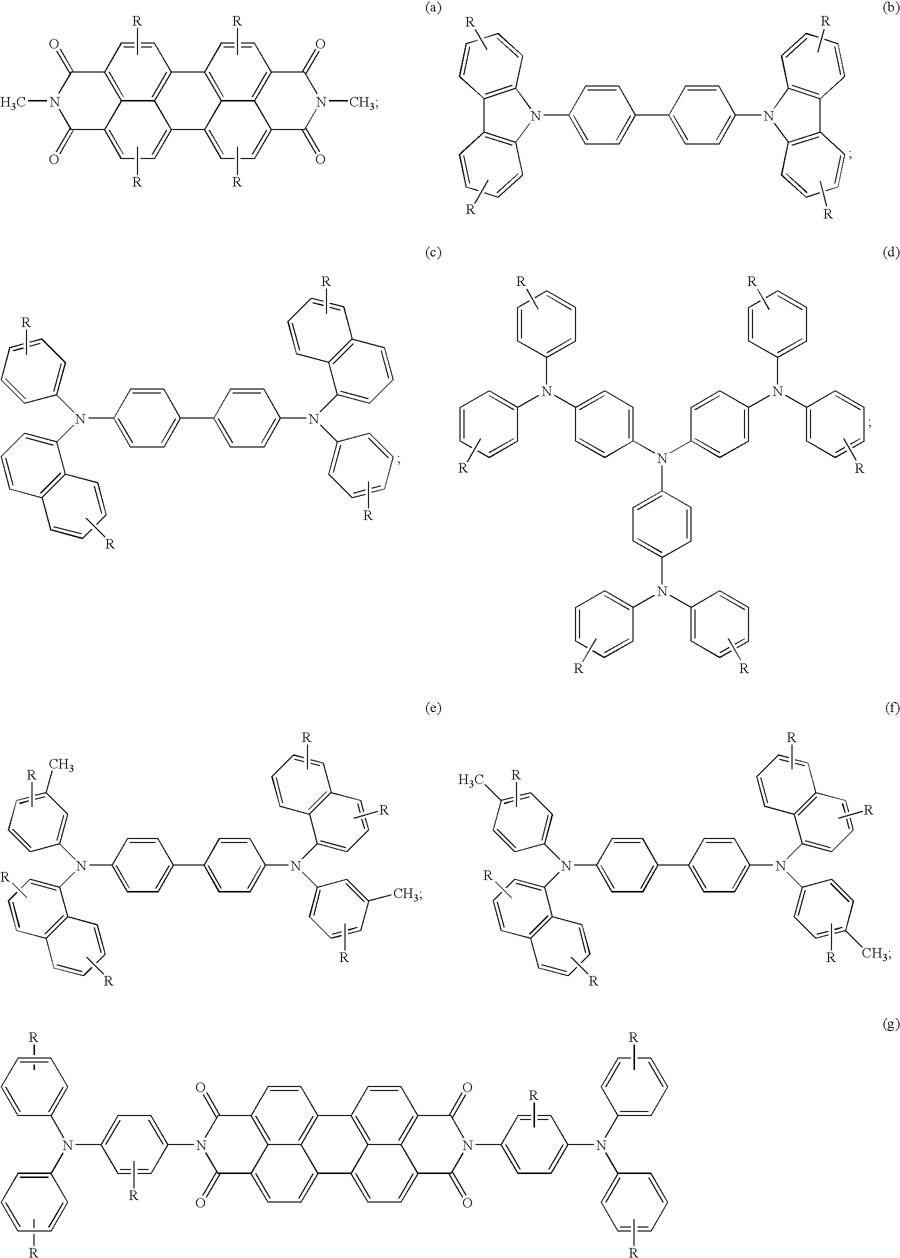
wherein the groups R in any of the formulae in (a) to (g) can be the same or different and are selected from hydrogen; substituted and unsubstituted aliphatic groups; substituted and unsubstituted aromatic, heterocyclic and polycyclic ring structures; halogens; and thiophenyl groups;
(h) N,N′-diphenyl-N,N′-di(naphthalen-1-yl)-1,1′-biphenyl-4,4′-diamine (α-NBP);
(i) N,N′-diphenyl-N,N′-bis(3-methylphenyl)-1,1′-biphenyl-4,4′-diamine (TPD);

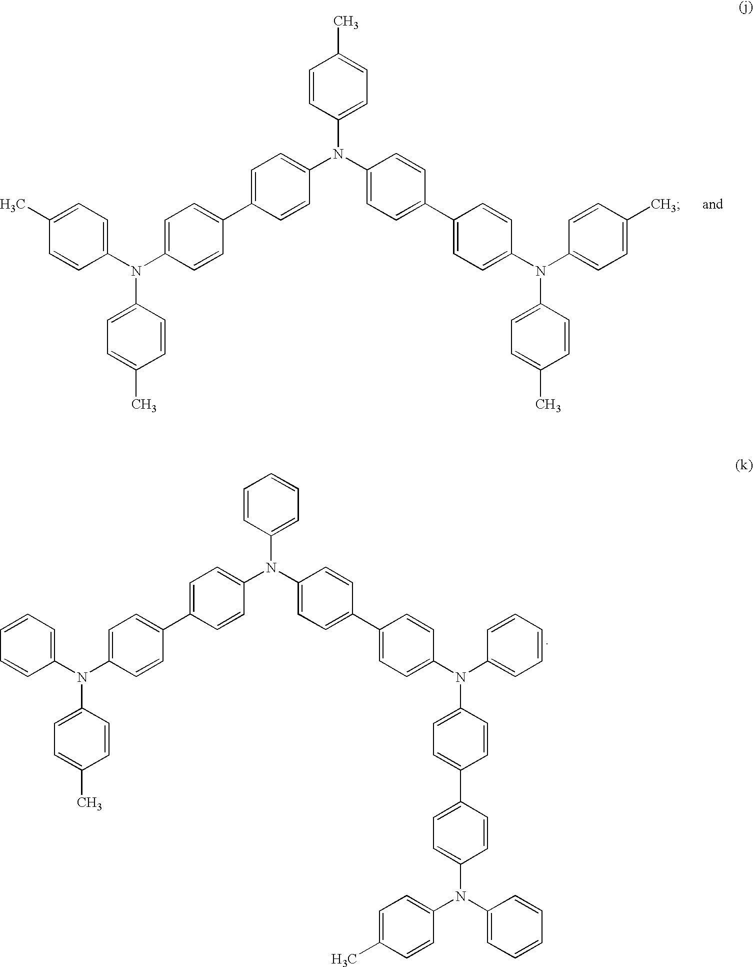

44. The device of claim 41, wherein the hole transport material is selected from the group consisting of: 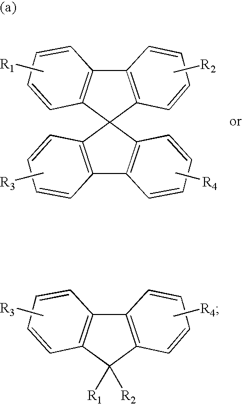
wherein the groups R₁-R₄ when appearing in either of the above formulae can be the same or different and are selected from hydrogen; substituted and unsubstituted aliphatic groups; substituted and unsubstituted aromatic, heterocyclic and polycyclic ring structures; halogens; and thiophenyl groups; and,
(b) any of:
a polymer of an amino-substituted aromatic compound;
poly(p-phenylene vinylene) or a copolymer including poly(p-phenylene vinylene);
poly(2,5-dialkoxyphenylene vinylene);
a polyfluorene;
an oligofluorene;
a polyphenylene;
an oligophenylene;
a polyanthracene;
an oligoanthracene;
a polythiophene; and,
an oligothiophene.

45. The device of claim 40, in which the metal quinolate is a metal combined with a quinolate ligand according to the general chemical formula 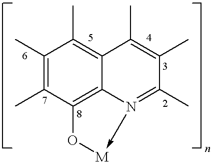
where M is the metal; n is the valence state of the metal; and where the substituents may be the same or different in the 2, 3, 4, 5, 6 and 7 positions and are selected from the group of substituents consisting of hydrogen, alkyl, alkoxy, aryl, aryloxy, sulphonic acids, esters, carboxylic acids, amino and amido groups, aromatic, polycyclic or heterocyclic groups, and an oxoquinolate having the general chemical formula
q₂M^{IV}═O
or
q₃M^{V}═O
wherein q₂ and q₃ represent quinolate ligands as defined above and O is oxygen.

46. The device of claim 45, wherein the metal quinolate is a 2-methyl or 5-methyl metal quinolate.

47. The device of claim 45, wherein the metal M is a four-valence state metal selected from titanium, zirconium and hafnium or a five-valence state metal selected from vanadium, niobium and tantulum.

48. The device of claim 45, wherein the metal quinolate is zirconium quinolate, zirconium 2-methylquinolate or zirconium 5-methylquinolate.

49. The device of claim 40, wherein the dopant is selected from the group consisting of diphenylacridine, coumarins, perylene, porphoryin, porphines, pyrazalones and their derivatives, and a second quinolate different from the first quinolate.

50. The device of claim 40, wherein the dopant is selected from the group consisting of:
(a) 4-(5-(pyridin-2-yl)-1H-pyrazol-3-yl)benzonitrile; 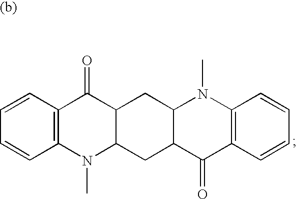
(c) compounds of the general chemical formula A or B 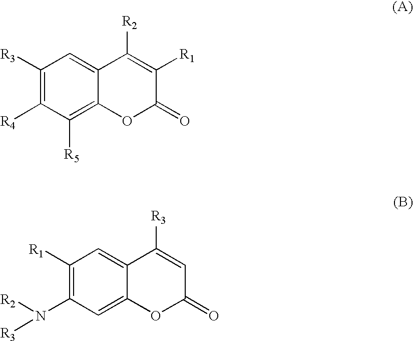
where R₁ is chosen from the group consisting of hydrogen, carboxy, alkanoyl, alkoxycarbonyl, cyano, aryl, and a heterocylic aromatic group; R₂ is chosen from the group consisting of hydrogen, alkyl, haloalkyl, carboxy, alkanoyl, and alkoxycarbonyl; R₃ is chosen from the group consisting of hydrogen and alkyl; R₄ is an amino group; and Rs is hydrogen; or alternatively R₁ or R₂ together form a fused carbocyclic ring, and/or the amino group forming R⁴ completes in combination with at least one of R⁴ and R⁶ a fused ring, being five six or seven membered rings, the heterocyclic aromatic groups containing 5 or 6 membered heterocyclic rings containing carbon atoms and one or two heteroatoms chosen from the group consisting of oxygen, sulphur, and nitrogen;
(d) the following compounds:
7-diethylamino-4-methylcoumarin;
4,6-dimethyl-7-ethylaminocoumarin;
4-methylumbelliferone;
3-(2′-benzothiazolyl)-7-diethylaininocoumarin;
3-(2′-benzimidazolyl)-7-N,N-diethylaminocoumarin;
7-amino-3-phenylcoumarin;
3-(2′-N-methylbenzimidazolyl)-7-N,Ndiethylaminocoumarin;
7-diethylamino-4-trifluoromethylcoumarin;
2,3,5,6-1H,4H-tetrahydro-8-methylquinolazino[9,9a,1 -gh]coumarin;
cyclopenta[c]julolindino[9,10-3]-11H-pyran-11-one;
7-amino-4-methylcoumarin;
7-dimethylaminocyclopenta[c]coumarin;
7-amino-4-trifluoromethylcoumarin;
7-dimethylamino-4-trifluoromethylcoumarin;
1,2,4,5,3H,6H,10H-tetrahydro-8-trifluoromethyl[1]benzopyrano[9,9a,1-gh]quinolizin-10-one;
4-methyl-7-(sulfomethylamino)coumarin sodium salt;
7-ethylamino-6-methyl-4-trifluoromethylcoumarin;
7-dimethylamino-4-methylcoumarin;
1,2,4,5,3H,6H,10H-tetrahydro carbethoxy[1]benzopyrano[9,9a, 1-gh]quinolizino-10-one;
9-acetyl-1,2,4,5,3H,6H, 10H-tetrahydro[1]benzopyrano[9,9a, 1-gh]quinolizino-10-one;
9-cyano-1,2,4,5,3H,6H, 10H-tetrahydro[1]benzopyrano[9,9a, 1 -gh]quinolizino-10-one;
9-(t-Butoxycarbonyl)-1,2,4,5,3H,6H, 10H-tetrahyro[1 ]benzopyrano[9,9a, 1 -gh]quinolizino-10-one;
4-methylpiperidino[3,2-g]coumarin;
4-trifluoromethylpiperidino[3,2-g]coumarin;
9-carboxy-1,2,4,5,3H,6H, 10H-tetrahydro[1]benzopyrano[9,9a, 1-gh]quinolizino-10-one;
N-ethyl-4-trifluoromethylpiperidino[3,2-g] coumarin; 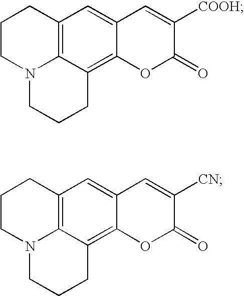
4-methylumbelliferone;
7-dimethylamino-4-trifluoromethylcoumarin;
umbelliferone;
4-methyl-3-cyanoumbilliferone;
3-cyanoumbelliferone;
3-(1H-benzo[d]imidazol-2-yl)-8-(diethylamino)-2H-benzo[g]chromen-2-one;
3-(benzo[d]thiazol-2-yl)-8-(diethylamino)-2H-benzo[g]chromen-2-one;
(e) compounds of the general chemical formula 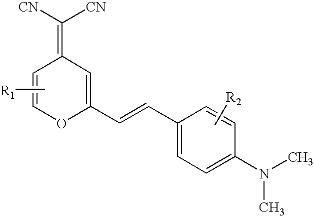
wherein R₁ and R₂, which may be the same or different, are selected from: hydrogen; hydrocarbyl groups; substituted and unsubstituted aromatic, heterocyclic and polycyclic ring structures; fluorocarbons; halogen; thiophenyl; substituted or unsubstituted fused aromatic, heterocyclic and polycyclic ring structures; and copolymerizable monomer residues of formula —CH₂—CH═CH—R wherein R is hydrocarbyl, aryl, heterocyclic, carboxy, aryloxy, hydroxy, alkoxy, amino or substituted amino; 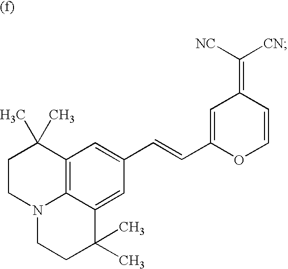
(g) compounds of the general chemical formula 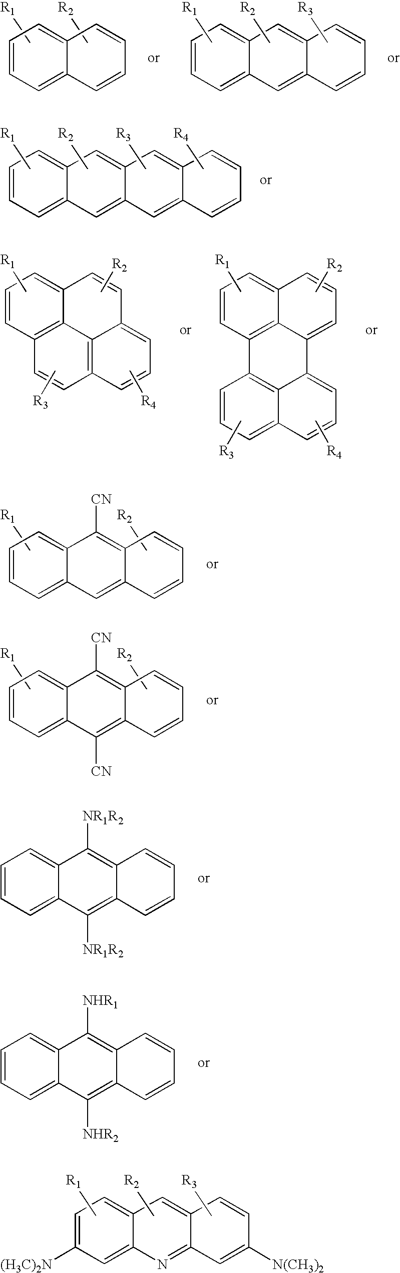
wherein R₁ to R_{4,} which may be the same or different, are selected from hydrogen; hydrocarbyl groups; substituted and unsubstituted aromatic, heterocyclic and polycyclic ring structures; fluorocarbons; halogen; thiophenyl; substituted or unsubstituted fused aromatic, heterocyclic and polycyclic ring structures; and copolymerizable monomer residues of formula —CH₂—CH═CH—R wherein R is hydrocarbyl, aryl, heterocyclic, carboxy, aryloxy, hydroxy, alkoxy, amino or substituted amino;
(h) 5,6,11,12-tetraphenyltetracene,
10-(anthracen-10-yl)anthracene,
9-(10-oxoanthracen-9(10H)-ylidene)anthracen-10(9H)-one; 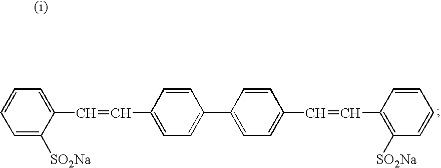
(j) fluorescent 4-dicyanomethylene4H-pyrans and 4-dicyanomethylene-4H-thiopyrans;
(k) cyanines; merocyanines; complex cyanines and merocyanines; tri-, tetra- and poly-nuclear cyanines and merocyanines; oxanols; hemioxonols; styryls; merostyryls; streptocyanines; 4-oxo-4H-benz-[d,e]anthracenes; pyrylium;
thiapyrylium; selenapyrylium; and telluropyrylium dyes; and,
(l) fluorescent transition metal and rare earth complexes.

51. The device of claim 40, wherein the doped metal quinolate electron transport layer has a thickness of about 10-50 nm.

52. The device of claim 40, wherein there is up to 10 mole percent fluorescent material, based on the moles of transition metal quinolate.

53. The device of claim 40, wherein there is up to 1 mole percent fluorescent material, based on the moles of transition metal quinolate.

54. The device of claim 40, wherein there is less than 10⁻³ mole percent fluorescent material, based on the moles of transition metal quinolate.

55. The device of claim 40, wherein there is a layer comprising zirconium quinolate between the layer of electroluminescent material and the second electrode.

56. The device of claim 40, wherein the electroluminescent material is mixed with a hole transmitting material.

57. The device of claim 40, wherein the first electrode is a transparent, electricity-conducting glass electrode.

58. The device of claim 40, wherein the second electrode is selected from the group consisting of aluminum, calcium, lithium, magnesium and alloys thereof, and silver/magnesium alloys.
